(19) United States
(12) Patent Application Publication
(10) Pub. No.: US 2025/0300569 A1
(43) Pub. Date: Sep. 25, 2025

(54) POWER MODULE FOR ELECTRIFIED VEHICLE

(71) Applicant: FORD GLOBAL TECHNOLOGIES, LLC, Dearborn, MI (US)

(72) Inventors: Man Prakash Gupta; Kewei Xiao; Michael W Degner

(21) Appl. No.: 18/610,678

(22) Filed: Mar. 20, 2024

(51) Int. Cl. H02M 7/00; B60L 50/51; H02M 1/00; H02M 7/48; H05K 7/14

(52) U.S. Cl. CPC H02M 7/003; B60L 50/51; H02M 1/0067; H02M 7/48; H05K 7/14329; B60L 2210/40

(57) ABSTRACT

A three-phase power electronics module for an electric vehicle utilizes capacitor modules interspersed with power modules. Different methods are proposed for making the electrical connections between the capacitor modules and the power modules. One method utilizes bus bars which include overlapping planar regions. Another method utilizes the terminals of the capacitor modules to connect to the DC terminals of the adjacent power modules.

### TECHNICAL FIELD

The present invention relates to a power electronics module for an electrified vehicle. More particularly, it relates to means of electrically connecting capacitor modules and power modules that make up the power electronics module.

### BACKGROUND

Electric and hybrid vehicles may include power modules that are configured to convert electrical power from direct electrical current (DC) into alternating electrical current (AC) and/or vice versa.

### SUMMARY

A three-phase power electronics module includes three power modules, at least two capacitor modules and two bus bars. The three power modules are arranged in a row. Each power module has a positive DC terminal, a negative DC terminal, and an AC terminal and is configured to convert DC electrical power delivered via the two DC terminals into AC electrical power at the AC terminal. The capacitor modules are interspersed between the power modules. A third capacitor module may be located at one end of the three power modules. Each capacitor module has a positive terminal and a negative terminal. A first bus bar, having a first planar region, electrically connects the positive DC terminals of the power modules and the positive terminals of the capacitor modules. A second bus bar, having a second planar region overlapping and spaced apart from the first planar region, electrically connects the negative DC terminals of the power modules and the negative terminals of the capacitor modules. An insulator may separate the first planar region from the second planar region. The first planar region and second planar surface may be parallel to or perpendicular to a top surface from which the DC terminals extend. One of the bus bars may have a stepped profile or one of the DC terminals may extend farther from the top surface than the other.

A three-phase power electronics module includes three power modules and at least two capacitor modules. The three power modules are arranged in a row. Each power module has a positive DC terminal, a negative DC terminal, and an AC terminal and is configured to convert DC electrical power delivered via the two DC terminals into AC electrical power at the AC terminal. The two capacitor modules are interspersed between the power modules. Each capacitor module has a positive terminal and a negative terminal. The positive terminal of each capacitor module extends between and is electrically connected with the positive DC terminals of adjacent power modules. The negative terminal of each capacitor module extends between and is electrically connected with the negative DC terminals of adjacent power modules. Each power module may include a housing defining two slots each providing access to one of the two DC terminals. Each of the power modules may also include a set of signal terminals extending through the housing. Each of the capacitor modules may include a housing which abuts the housing of adjacent power modules. A third capacitor module may be adjacent to an outside power module of the three power modules. An end plate may abut the housing of the third capacitor module. The end plate may define two slots through which the positive DC terminal and the negative DC terminal of the third capacitor module extend.

A capacitor module for a power electronics module includes a capacitor element, positive and negative terminals, and an over-molded housing. The capacitor element has first and second charge collectors. The positive and negative terminals are each electrically connected one of the charge collectors. Each of the terminals includes a tab extending through a first side of the housing and another tab extending through a second side of the housing opposite the first side. The tabs may be aligned or may be offset.

### BRIEF DESCRIPTION OF THE DRAWINGS

FIG. 1 illustrates a block diagram of an electric vehicle.

FIG. 2 illustrates a schematic diagram of components of an electric drive system of the electric vehicle, the components of the electric drive system including a traction battery, a power electronics module having a DC-link capacitor and an inverter, and a motor.

FIG. 3 is a pictorial view of a three-phase power electronics module.

FIG. 4 is a pictorial view of the three-phase power electronics module of FIG. 3 with overlapping bus bars in a first configuration.

FIG. 5 is a cross sectional view of the bus bars of FIG. 4 according to a first configuration.

FIG. 6 is a cross sectional view of the bus bars of FIG. 4 according to a first configuration.

FIG. 7 is a pictorial view of the three-phase power electronics module of FIG. 3 with overlapping bus bars in a second configuration.

FIG. 8 is a pictorial view of the three-phase power electronics module of FIG. 3 with overlapping bus bars in a third configuration.

FIG. 9 is a pictorial view of the three-phase power electronics module of FIG. 3 with overlapping bus bars in a fourth configuration.

FIG. 10 is a pictorial view of the three-phase power electronics module of FIG. 3 with overlapping bus bars in a fifth configuration.

FIG. 11 is a pictorial view of internal components of a power module.

FIG. 12 is a pictorial view of a power module including the internal components illustrated in FIG. 11 and an over-molded housing.

FIG. 13 is a pictorial view of internal components of a capacitor module.

FIG. 14 is a pictorial view of a capacitor module including the internal components illustrated in FIG. 13 and an over-molded housing.

FIG. 15 is a pictorial view of internal components of a power module of FIG. 11 connected to the internal components of two adjacent capacitor modules of FIG. 13.

FIG. 16 is a pictorial view of the three-phase power electronics module utilizing the power modules of FIGS. 11 and 12 and the capacitor modules of FIGS. 13 and 14 connected as illustrated in FIG. 15.

FIG. 17 is a pictorial view of internal components of a power module of FIG. 11 connected to the internal components of two adjacent capacitor modules with an alternative design.

FIG. 18 is a pictorial view of internal components of a power module having an alternative design connected to the internal components of two adjacent capacitor modules with an alternative design.

### DETAILED DESCRIPTION

Detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

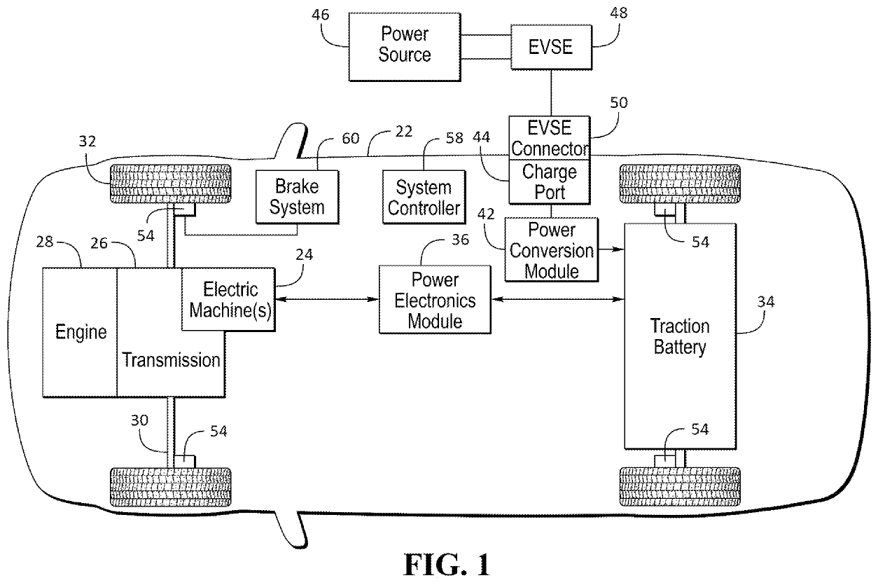

Referring now to FIG. 1, a block diagram of an exemplary electric vehicle (“EV”) 22 is shown. In this example, EV 22 is a plug-in hybrid electric vehicle (PHEV). EV 22 includes one or more electric machines 24 (“e-machines”) mechanically connected to a transmission 26. Electric machine 24 is capable of operating as a motor and as a generator. Transmission 26 is mechanically connected to an engine 28 and to a drive shaft 30 mechanically connected to wheels 32. Electric machine 24 can provide propulsion and slowing capability while engine 28 is turned on or off. Electric machine 24 acting as a generator can recover energy that may normally be lost as heat. Electric machine 24 may reduce vehicle emissions by allowing engine 28 to operate at more efficient speeds and allowing EV 22 to be operated in electric mode with engine 28 off under certain conditions.

A traction battery 34 (“battery) stores energy that can be used by electric machine 24 for propelling EV 22. Battery 34 typically provides a high-voltage (HV) direct current (DC) output. Battery 34 is electrically connected to a power electronics module 36. Power electronics module 36 is electrically connected to electric machine 24 and provides the ability to bi-directionally transfer energy between battery 34 and the electric machine. For example, battery 34 may provide a DC voltage while electric machine 24 may require a three-phase alternating current (AC) voltage to function. Power electronics module 36 may convert the DC voltage to a three-phase AC voltage to operate electric machine 24. In a regenerative mode, power electronics module 36 may convert three-phase AC voltage from electric machine 24 acting as a generator to DC voltage compatible with battery 34.

Battery 34 is rechargeable by an external power source 46 (e.g., the grid). Electric vehicle supply equipment (EVSE) 48 is connected to external power source 46. EVSE 48 provides circuitry and controls to control and manage the transfer of energy between external power source 46 and EV 22. External power source 46 may provide DC or AC electric power to EVSE 48. EVSE 48 may have a charge connector 50 for plugging into a charge port 44 of EV 22. Charge port 44 may be any type of port configured to transfer power from EVSE 48 to EV 22. A power conversion module 42 of EV 22 may condition power supplied from EVSE 48 to provide the proper voltage and current levels to battery 34. Power conversion module 42 may interface with EVSE 48 to coordinate the delivery of power to battery 34. Alternatively, various components described as being electrically connected may transfer power using a wireless inductive coupling.

The various components discussed may have one or more associated controllers to control and monitor the operation of the components. The controllers can be microprocessor-based devices. The controllers may communicate via a serial bus (e.g., Controller Area Network (CAN)) or via discrete conductors. For example, a system controller 58 (i.e., a vehicle controller) is present to coordinate the operation of the various components.

As described, EV 22 is in this example is a PHEV having engine 28 and battery 34. In other embodiments, EV 22 is a battery electric vehicle (BEV). In a BEV configuration, EV 22 does not include an engine.

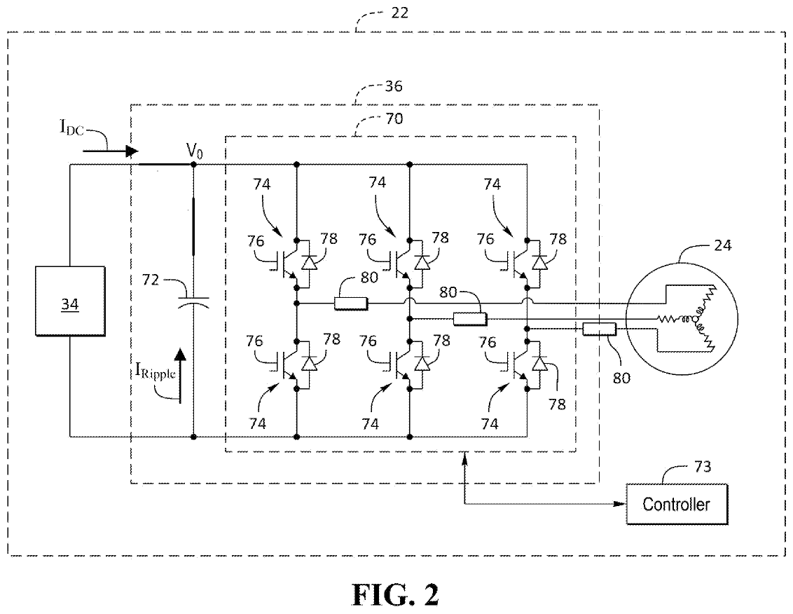

Referring now to FIG. 2, with continual reference to FIG. 1, a schematic diagram of components of an electric drive system of EV 22 is shown. As shown in FIG. 2, the electric drive system of EV 22 includes traction battery 34, power electronics module 36, and electric machine (i.e., “motor”) 24.

As described above, power electronics module 36 is coupled between battery 34 and motor 24. Power electronics module 36 converts DC electrical power provided from battery 34 into AC electrical power for providing to motor 24. In this way, power electronics module 36 drives motor 24 with power from battery 34 for the motor to propel EV 22.

Power electronics module 36 includes a DC-link capacitor 72 and an inverter 70 (or “inverter control system” (“ICS”)). Inverter 70 shown in FIG. 2 is an exemplary inverter. DC-link capacitor 72 is disposed between battery 34 and inverter 70 and is connected in parallel with battery 34. DC-link capacitor 72 is operable to absorb ripple currents generated by operation of power switches of inverter 70 and stabilize a DC-link voltage Vo for inverter 70 control.

As known to those of ordinary skill, inverters convert DC power to multi-phase AC power (three-phase being most common). Inverters can move electrical power in either direction (bi-directional) either driving an electric machine (i.e., motoring) or electrically slowing the electric machine (i.e., generating). An inverter system is made up of a combination of power electronic hardware (switches) and control software (FIG. 2 is a representative drawing). Electrical current can be quickly adjusted by opening and closing the power switches in the inverter.

Many inverter systems, including inverters relevant to embodiments of the present invention such as inverter 70, perform closed loop current control to precisely control the e-machine. To achieve this, the electric current in each phase of the inverter is sensed with a current sensor and a corresponding signal is provided to the controller of the inverter system. The most common approach is to sense all of the phases, but any one phase current can be inferred from knowledge of the other phase currents. The current sensor can use and/or be implemented in different technologies and current sensors 80 shown in FIG. 2, discussed below, are but one example. Such current sensors are typically integrated into the inverter.

Inverter 70 includes inverting circuitry and a plurality of power switching units 74. As known to those of ordinary skill, in the exemplary example, inverter 70 includes three sets of pairs of power switching units 74 (i.e., three x two=a total of six power switching units 74 as shown in FIG. 2). Each pair of power switching units 74 includes two power switching units 74 connected in series. Each power switching unit 74 includes a power switch 76, in the form a transistor, arranged anti-parallel with a diode 78. In this example, the transistor is an insulated gate bipolar transistor (IGBT). Each pair of power switching units 74 is connected in parallel with battery 34 and DC-link capacitor 72 and thereby each pair of power switching units forms a “phase” of inverter 70. In this way, inverter 70, having three pairs of power switching units 74, is a three-phase inverter operable for converting DC electrical power from battery 34 into three-phase AC electrical power for provision to motor 24.

Further, each phase of inverter 70 includes a current sensor 80. For instance, each current sensor 80 is a resistive shunt connected in series with the output of the corresponding phase. Current sensors 80 are operable for sensing the electrical current (I_{AC}) outputted from the corresponding phases of inverter 70 to motor 24.

Power electronics module 36 has an associated controller 73. Controller 73 can be a microprocessor-based device. Controller 73 is configured to monitor operation of DC-link capacitor 72 and to monitor and control operation of inverter 70. Particularly, controller 73 is operable to control the operation of power switches 76 to cause inverter 70 to convert a given DC electrical power provided from battery 34 via DC-link capacitor 72 into a desired AC electrical power for providing to motor 24. Controller 73 is in communication with current sensors 80 to monitor the AC electrical power provided from inverter 70 to motor 24. Controller 73 uses information of current sensors 80 as feedback in controlling inverter 70 to output the desired AC electrical power to motor 24.

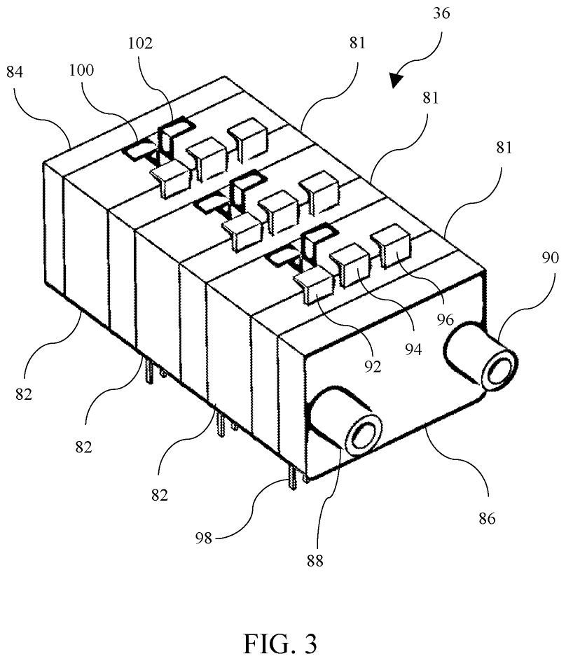

FIG. 3 is a pictorial view of a three-phase power electronics module 36. The switches of inverter 70 are distributed among three power modules 81. The DC-link capacitor is implemented using three capacitor modules 82. The power modules 81 and the capacitor modules 82 are interleaved with one another. As will be discussed on more detail below, each power module and each capacitor module include an over-molded housing. These housings along with end covers 84 and 86, collectively form a power module housing. End cover 86 includes an inlet port 88 and an outlet port 90 for cooling fluid. The housings of the power modules and capacitor modules collectively form a number of fluid passageways to route the cooling fluid past heat generating components, as described more completely in U.S. patent application Ser. No. 18/488,223 filed Nov. 17, 2023 which is hereby incorporated by reference.

Each power module includes a positive DC terminal 92, a negative DC terminal 94, and an AC output terminal 96. Terminal 92 is to be electrically connected to the positive terminal of battery 34. Terminal 94 is to be electrically connected to the negative terminal of battery 34. Terminal 96 is to be electrically connected to one of the phase leads of motor 24. Two elements are electrically connected if an electrical path is established between the elements by either direct contact or via one or more electrically conductive components. Each power module 81 includes one pair of power switching units 74. Each power module is configured to convert Direct Current (DC) power delivered via the DC terminals into one phase of AC power delivered via terminal 96 based on control signals received via a set of signal terminals 98.

Each capacitor module includes a positive terminal 100 and a negative terminal 102. Terminal 100 is to be electrically connected to the positive DC terminals of the power modules and the positive terminal of battery 34. Terminal 102 is to be electrically connected to the negative DC terminals of the power modules and the negative terminal of battery 34.

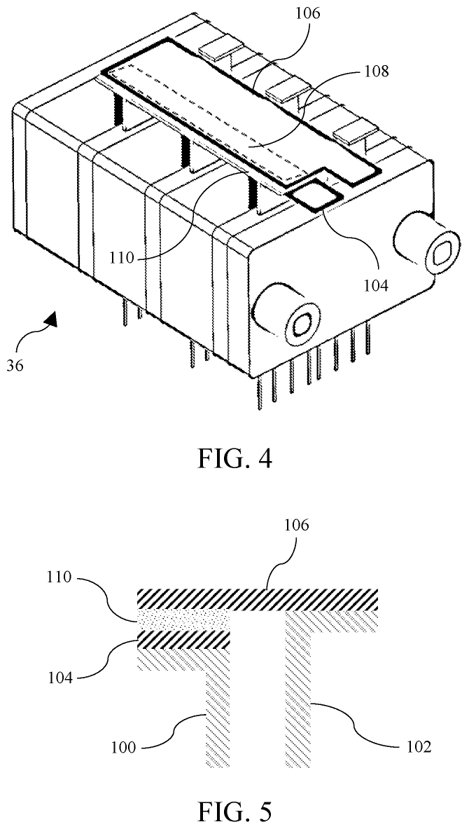

FIG. 4 illustrates one way in which the electrical connections mentioned above may be accomplished. Positive bus bar 104 electrically connects all of the positive DC terminals 92 of the three power modules 81 and all of the positive terminals 100 of the three capacitor modules 82. Similarly, negative bus bar 106 electrically connects all of the negative DC terminals 94 of the three power modules 81 and all of the negative terminals 102 of the three capacitor modules 82. The bus bars are sheet metal parts made of electrically conductive materials such as copper or aluminum. The bus bars are held in contact with the terminals, such as by spot welds. Both bus bars include a planar region 108 that overlaps with the other bus bar. This facilitates flux cancellation and reduces parasitic power loop inductance. An insulating layer 110 separates the two bus bars from one another and prevents the flow of electric current between them. The insulating layer 110 is made of an electrically non-conductive material such as paper.

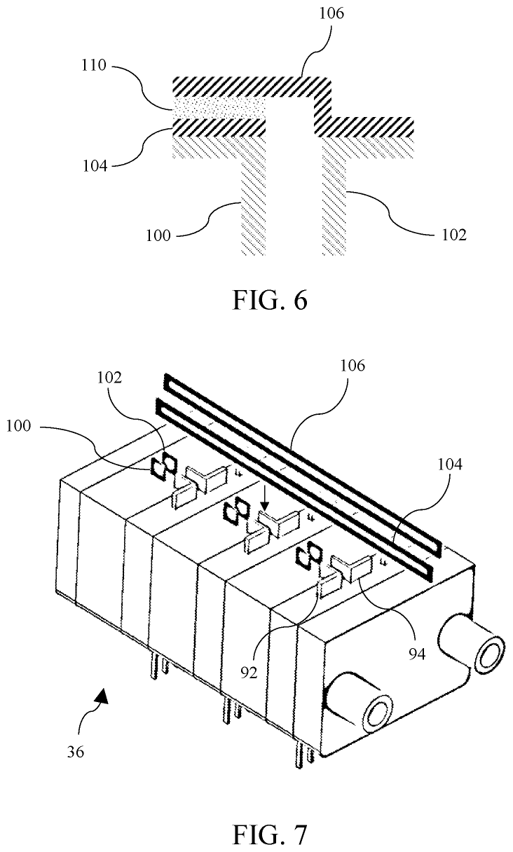

FIGS. 5 and 6 illustrate two different ways to achieve electrical contact between the terminals 100 and 102 of the capacitor modules and the bus bars 104 and 106 in the embodiment of FIG. 4. These same options also achieve electrical contact between the DC terminals 92 and 94 of the power modules and the bus bars. In the embodiment of FIG. 5, terminal 102 extends farther from the top surface of the housing to accommodate the thickness of bus bar 104 and insulator 110. In the embodiment of FIG. 6, terminals 100 and 102 extend the same distance, but bus bar 106 has a stepped profile to accommodate the thickness of bus bar 104 and insulator 110.

FIG. 7 illustrates another embodiment. In this embodiment, the terminals 92, 94, 100, and 102 all have vertical portions which extend from the tops of the respective housings providing a surface that is parallel with the sides of the respective housings. The terminals may also have other surfaces. Bus bars 104 and 106 make contact against these vertical surfaces. An insulator (not shown) may separate the busbars from one another. In addition to a slight interference fit, the busbars may be spot welded to the terminals. In this embodiment, the entire bus bar constitutes the planar region which overlap to provide flux cancellation.

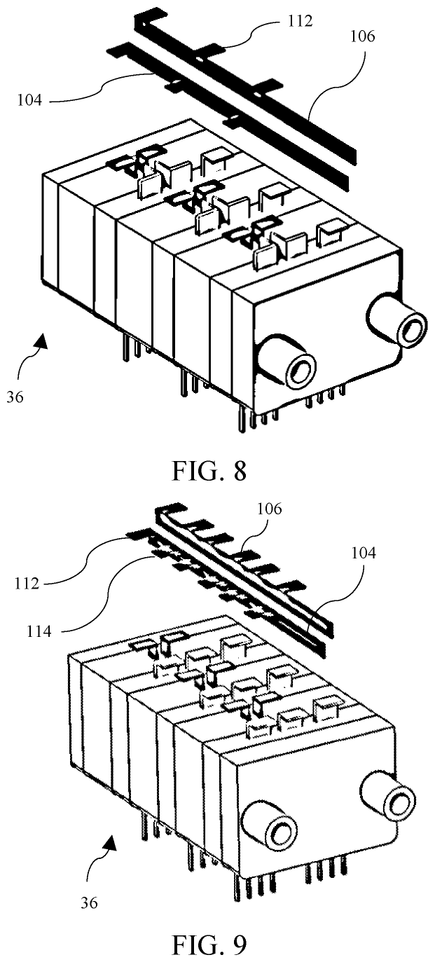

FIG. 8 illustrates another embodiment. In this embodiment, the busbars 104 and 106 include a set of first tabs 112 which extend at right angles to the planar regions. These first tabs may be spot welded to corresponding tabs on the positive and negative terminals of the capacitor modules. In the embodiment of FIG. 9, the busbars also include a set of second tabs 114 which extend at right angles from the planar regions. These second tabs may be spot welded to corresponding tabs on the positive DC terminals and negative DC terminals of the power modules.

In the embodiment of FIG. 10, each of the busbars include a set of connectors 116 extending at right angles to the planar regions. First tabs 118 and second tabs 120 extend from the connectors at right angles to both the planar regions and the connectors. The first tabs are spot welded to positive and negative terminals of the capacitor modules. The second tabs are spot welded to the positive DC terminal and the negative DC terminals of the power modules.

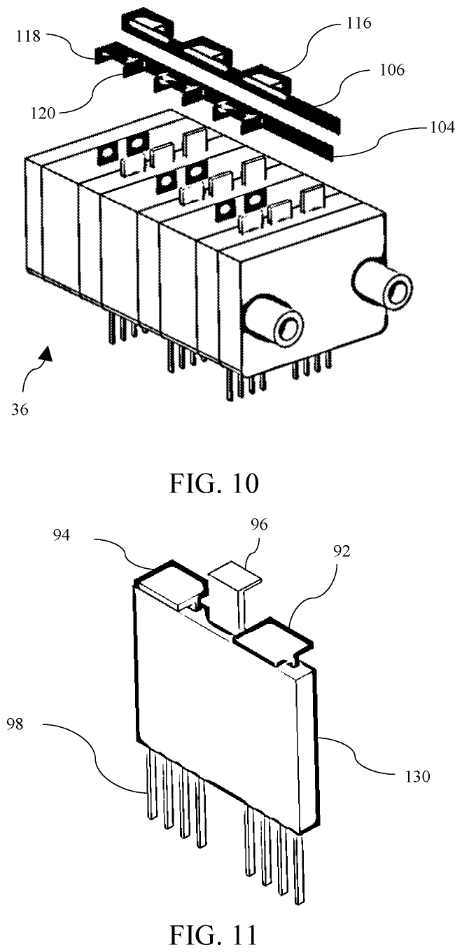

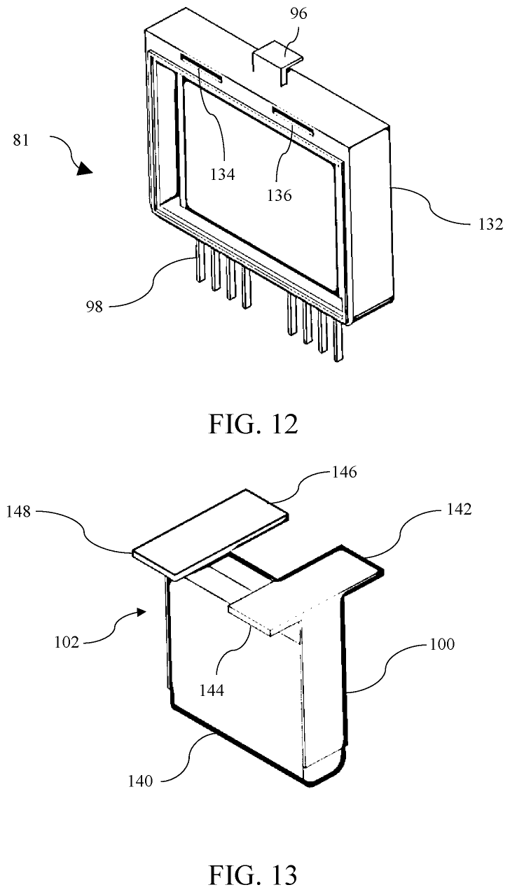

FIGS. 11-18 illustrate a different design concept for electrically connecting the components of the three-phase power module. FIG. 11 illustrates a power module prior to molding the housing. Circuit board 130 includes two power switching units 74 and one current sensors 80. Signal terminals 98 extend from one edge of the circuit board 130. Positive DC terminal 92, negative DC terminal 94, and AC output terminal 96 extend from another edge of circuit board 130. AC output terminal 96 extends farther from the edge than either of the DC terminals. The DC terminals include a surface perpendicular to the circuit board 130. FIG. 12 illustrates a power module 81 after over-molding a housing 132 onto the assembly of FIG. 11. AC output terminal 96 and signal terminals 98 extend through the housing 132. The housing includes two through slots 134 and 136 which provide access to the positive DC terminal 92 and the negative DC terminal 94.

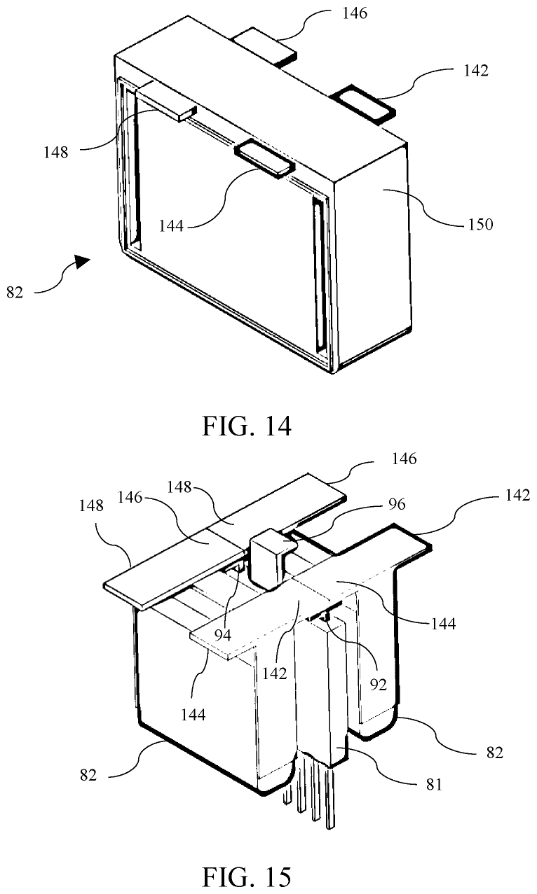

FIG. 13 illustrates a capacitor module prior to molding the housing. Capacitor element 140 includes two charge collectors. One charge collector is electrically connected to positive terminal 100 and the other charge collector is electrically connected to negative terminal 102. Positive terminal 100 includes a first tab 142 extending in one direction and a second tab 144 extending in an opposite direction. Similarly, negative terminal 102 includes a third tab 146 extending in one direction and a fourth tab 148 extending in an opposite direction. FIG. 14 illustrates a capacitor module 82 after over-molding a housing 150 onto the assembly of FIG. 13. Tabs 142, 144, 146, and 148 extend through the housing 150.

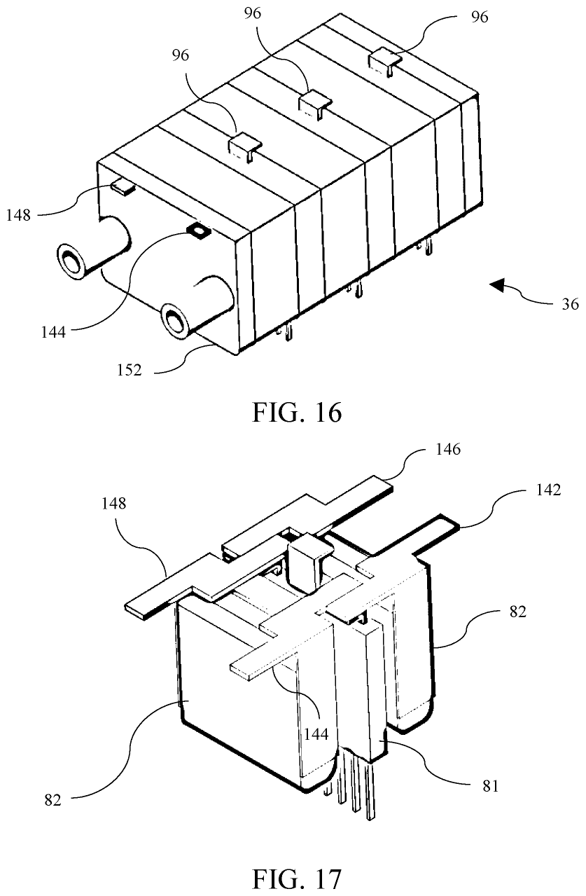

FIG. 15 illustrates how a power module 81 is connected to the adjacent capacitor modules 82. The modules are shown without the housings so that the connections are visible. First tab 142 of one capacitor module and second tab 144 of the other capacitor module both extend into the slot 136 to make contact with positive DC terminal 92. Similarly, third tab 146 of one capacitor module and fourth tab 148 of the other capacitor module both extend into the slot 138 to make contact with negative DC terminal 94. The connections to the other two power modules are similar, except that the power module on the end may have a capacitor module on only one side. FIG. 16 shows the fully assembled three-phase power electronics module 36 with the over-molded housings. An end plate 152 has slots through which the second tab 144 and fourth tab 148 of one of the capacitor modules extends. This provides access to connect to three-phase power electronics module to battery 34.

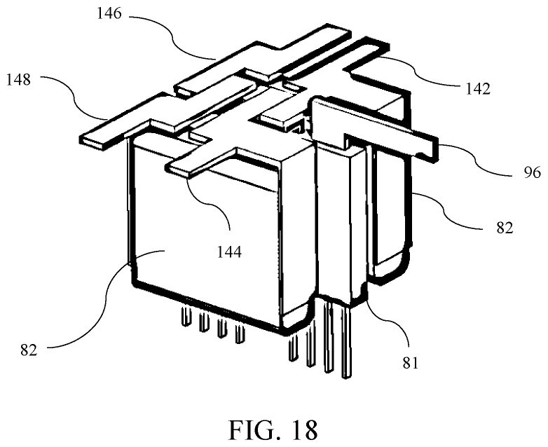

FIGS. 17 and 18 illustrate some variations on the design concept. In the embodiment of FIG. 17, the first tab 142 is offset from the second tab 144, unlike the embodiment of FIGS. 13-15 in which they are aligned. This allows the tabs to extend across the positive DC terminals of the adjacent power modules for better contact. It also allows the tab of the end capacitor to extend farther through the end plate making the battery connection easier. In the embodiment of FIG. 18, the AC output terminal is located on one side of the DC terminal as opposed to being between them. In some installations, this permits more convenient connection of the motor.

While exemplary embodiments are described above, it is not intended that these embodiments describe all possible forms of the present invention. Rather, the words used in the specification are words of description rather than limitation, and it is understood that various changes may be made without departing from the spirit and scope of the present invention. Additionally, the features of various implementing embodiments may be combined to form further embodiments of the present invention.

What is claimed is:

1. A three-phase power electronics module, comprising:
three power modules arranged in a row, each module having a positive DC terminal, a negative DC terminal, and an AC terminal and configured to convert DC electrical power delivered via the two DC terminals into AC electrical power at the AC terminal;
two capacitor modules interspersed between the power modules, each capacitor module having a positive terminal and a negative terminal;
a first bus bar, having a first planar region, electrically connecting the positive DC terminals of the power modules and the positive terminals of the capacitor modules; and
a second bus bar, having a second planar region overlapping and spaced apart from the first planar region, electrically connecting the negative DC terminals of the power modules and the negative terminals of the capacitor modules.

2. The three-phase power electronics module of claim 1, further comprising a third capacitor module at one end of the three power modules, the third capacitor module having a positive terminal electrically connected to the first bus bar and a negative terminal electrically connected to the second bus bar.

3. The three-phase power electronics module of claim 1, further comprising an insulator between the first planar region and the second planar region.

4. The three-phase power electronics module of claim 1, wherein:
the DC terminals of the power modules and the terminals of the capacitor modules extend from a top surface of the power electronics module; and
the first planar region and second planar surface are parallel to the top surface.

5. The three-phase power electronics module of claim 4, wherein one of the first bus bar and the second bus bar has a stepped profile.

6. The three-phase power electronics module of claim 4, wherein one of the positive DC terminals and the negative DC terminals extends farther from the top surface than the other of the positive DC terminals and the negative DC terminals and includes a portion parallel to the top surface which connects to a region of one of the first bus bar and the second bus bar that is not the first planar region or the second planar region.

7. The three-phase power electronics module of claim 1, wherein:
the DC terminals of the power modules and the terminals of the capacitor modules extend from a top surface of the power electronics module; and
the first planar surface and second planar surface are perpendicular to the top surface.

8. The three-phase power electronics module of claim 7, wherein:
each of the positive terminal and the negative terminal of each of the capacitor modules includes a tab which extends parallel to the top surface;
the first bus bar includes a plurality of tabs extending from the first planar region parallel to the top surface and electrically connected to the tabs of respective positive terminals; and
the second bus bar includes a plurality of tabs extending from the second planar region parallel to the top surface and electrically connected to the tabs of respective negative terminals.

9. The three-phase power electronics module of claim 7, wherein:
each of the positive DC terminal and the negative DC terminal of each of the power modules includes a tab which extends parallel to the top surface;
the first bus bar includes a plurality of tabs extending from the first planar region parallel to the top surface and electrically connected to the tabs of respective positive DC terminals; and
the second bus bar includes a plurality of tabs extending from the second planar region parallel to the top surface and electrically connected to the tabs of respective negative DC terminals.

10. The three-phase power electronics module of claim 7, wherein:
the first bus bar includes a plurality of first tabs extending perpendicular to the top surface and perpendicular to the first planar region, each first tab electrically connected to a positive DC terminals of a power module or to a positive terminal of a capacitor module; and
the second bus bar includes a plurality of second tabs extending perpendicular to the top surface and perpendicular to the second planar region, each second tab electrically connected to a negative DC terminals of a power module or to a negative terminal of a capacitor module.

11. A three-phase power electronics module, comprising:
three power modules arranged in a row, each module having a positive DC terminal, a negative DC terminal, and an AC terminal and configured to convert DC electrical power delivered via the two DC terminals into AC electrical power at the AC terminal; and
two capacitor modules interspersed between the power modules, each capacitor module having a positive terminal and a negative terminal, wherein
the positive terminal of each capacitor module extends between and is electrically connected with the positive DC terminals of adjacent power modules; and
the negative terminal of each capacitor module extends between and is electrically connected with the negative DC terminals of adjacent power modules.

12. The three-phase power electronics module of claim 11, wherein:
each power module includes a housing defining two slots each providing access to one of the two DC terminals; and
the AC terminal extends through the housing.

13. The three-phase power electronics module of claim 12, wherein:
each of the capacitor modules includes a housing which abuts the over-molded housing of an adjacent power modules; and
the positive terminals and the negative terminals of each of the capacitor modules extend into the slots of the adjacent power modules.

14. The three-phase power electronics module of claim 13, further comprising a third capacitor module adjacent to an outside power module of the three power modules, wherein:
the third capacitor module includes an over-molded housing which abuts the over-molded housing of outside power module;
a positive terminal of the third capacitor module extends into one of the slots of the outside power module and is electrically connected with the positive DC terminal of the outside power module; and
a negative terminal of the third capacitor module extends into the other slot of the outside power module and is electrically connected with the negative DC terminal of the outside power module.

15. The three-phase power electronics module of claim 14 further comprising an end plate abutting the housing of the third capacitor module, the end plate defining two slots through which the positive DC terminal and the negative DC terminal of the third capacitor module extend.

16. The three-phase power electronics module of claim 12, wherein each of the power modules further includes a set of signal terminals extending through the respective housing.

17. A capacitor module for a power electronics module, comprising:
a capacitor element having first and second charge collectors;
a positive terminal electrically connected to the first charge collector;
a negative terminal electrically connected to the second charge collector; and
an over-molded housing having a first side and a second side opposite the first side; wherein
the negative terminal includes a first tab extending through the first side and a second tab extending through the second side; and
the positive terminal includes a third tab extending through the first side and a fourth tab extending through the second side.

18. The capacitor module of claim 17 wherein:
the first tab is aligned with the second tab; and
the third tab is aligned with the fourth tab.

19. The capacitor module of claim 17 wherein:
the first tab is offset from the second tab; and
the third tab is offset from the fourth tab.
